(19) United States
(12) Patent Application Publication
(10) Pub. No.: US 2023/0085106 A1
(43) Pub. Date: Mar. 16, 2023

(54) CONTROLLED ORGANIC SEMICONDUCTOR DEVICE AND METHOD OF MANUFACTURING SAME

(71) Applicant: Technische Universitat Dresden, Dresden (DE)

(72) Inventors: Michael Sawatzki, Dresden (DE); Hans Kleemann, Dresden (DE); Karl Leo, Dresden (DE)

(21) Appl. No.: 17/904,270

(22) PCT Filed: Apr. 22, 2021
(86) PCT No.: PCT/EP2021/060531

§ 371 Date: Aug. 15, 2022

(30) Foreign Application Priority Data
Apr. 24, 2020 (DE) 10 2020 111 277.7

(51) Int. Cl. H01L 51/05

(52) U.S. Cl. CPC H01L 51/0504

(57) ABSTRACT

In various embodiments, there is provided a controlled organic semiconductor device comprising a crystalline first organic semiconductor layer on or over a substrate, the crystalline first organic semiconductor layer having a first conductivity type; and a crystalline second organic semiconductor layer on or over the first organic semiconductor layer, the crystalline second organic semiconductor layer having a second conductivity type, the first conductivity type being different from the second conductivity type.

Various embodiments relate to a controlled organic semiconductor device and method of manufacturing same.

Transistors are used in electronics in a wide variety of applications, for example for signal amplification and in logic circuits. These applications can be realized with bipolar transistors or field-effect transistors. For microelectronics in integrated circuits, field-effect transistors are usually used because they are easily miniaturized. Bipolar transistors can be superior to field-effect transistors in areas such as performance at high frequencies, frequency bandwidth, maximum current density, impedance matching, etc.

Bipolar transistors based on organic semiconductor materials have not yet been technically realized. Among other things, this is a consequence of the fundamental properties of most known organic semiconductor materials, since—in contrast to inorganic solids—most organic materials are structurally amorphous or can only be technically processed (e.g. deposited) in a structurally amorphous form. Amorphous materials generally exhibit low long-range order, which, in an organic device, can, for example, lead to inefficient charge carrier transport over long distances and/or a large number of interference and recombination sites. This in turn can lead to extremely short diffusion lengths, for example in the range of a few nanometers. However, for the function of a bipolar transistor, for example, a large diffusion length in the material forming the respective pn-np junction (or which forms the depletion zone) can be crucial.

In general, the diffusion length of charge carriers to recombination correlates with the degree of order in the system. High order organic semiconductor materials (organic (single) crystals) are usually grown in reactors using sublimation. Although the quality (order) of organic crystals can be high, the macroscopic size, shape, and orientation is random. This means that good quality organic semiconductor crystals can only be grown using costly and slow sublimation methods. Furthermore, such conventional organic crystals cannot directly be grown flat on substrates, but must further be transferred manually, which is laborious. For example, the thickness of the organic crystal may be in the range of several 100 nm to several micrometers. As a consequence, bipolar transistors based on these organic crystals must have a base length of at least one crystal thickness. Accordingly, the diffusion length would have to be at least as long.

A bipolar transistor requires a pn junction formed of two regions of different conductivity. The different conductivities are realized using different dopants. In organic crystals, the regions of different doping can only be achieved laterally or by stacking individual crystals. Doping of crystals grown in the reactor is not technically possible at present, since the sublimation temperature of the matrix and the dopant would have to match. Loose single crystals can only be doped through their surfaces, but this can result in uneven doping and/or incomplete doping. The minimum area dimension is thus given by the patterning method or the thickness of the crystals, which is in the range of several hundred nanometers or several micrometers. The advantage of having long diffusion lengths in organic crystals is outweighed by the thick layers.

Thus, it is a task to provide a controlled organic semiconductor device that reduces or eliminates one or more of the aforementioned problems and a method for manufacturing same.

In one aspect, a controlled organic semiconductor device is provided. The controlled organic semiconductor device comprises: a crystalline first organic semiconductor layer on or over a substrate, the crystalline first organic semiconductor layer having a first conductivity type; and a crystalline second organic semiconductor layer on or over the first organic semiconductor layer, the crystalline second organic semiconductor layer having a second conductivity type, the first conductivity type being different from the second conductivity type.

The use of crystalline organic semiconductor layers enables, for example, effective charge carrier transport. Thus, an efficient electrically switchable semiconductor device can be realized.

A pi-stacking of armorphic semiconducting polymer layers is not a crystalline organic semiconductor layer in the context of this description. Furthermore, no crystallinity of a semiconductor layer can be derived from a pi-stacking. Mere stacking of semiconducting polymer layers is, for example, not sufficient to ensure effective charge carrier transport.

A crystalline organic semiconductor layer has identical, identically oriented atomic groups aligned in a three-dimensional periodic arrangement extending over substantially the entire semiconductor layer.

With amorphous semiconducting polymer layers, one cannot derive any requirements for the periodicity of the atomic groups within the layers. As an illustrative example, a semiconducting polymer layer with “planar stacking” has individual, vertically stacked layers. However, from the feature “stacked” alone, no requirements can be derived for the composition of the layers, the orientation of the molecules in the individual layers or the stack of layers, or the periodicity in the stack of layers. Thus, a semiconducting polymer layer with planar stacking cannot describe a three-dimensional crystal.

Amorphous materials may have an internal structure formed of interconnected structural blocks. These structural blocks may be similar to the structural units of a corresponding crystalline phase of the same material. In contrast, the amorphous material lacks the common orientation of the structural blocks and periodicity throughout the material layer to be crystalline.

A semiconducting polymer layer with planar stacking may, but need not, exhibit pi-stacking. For example, a semiconducting polymer layer of an organic semiconducting material in “brickstone” structure may exhibit “pi-stacking”. Another semiconducting polymer layer of the same organic semiconducting material but in “herringbone” structure does not exhibit pi-stacking.

Furthermore, depending on the growth conditions, an organic semiconducting layer may have a completely disordered structure. In other words, a semiconducting polymer layer made of an organic semiconducting material can have a completely disordered structure or be crystalline, depending on the growth conditions.

Furthermore, in a layer stack of semiconducting polymer layers, the long-range order necessary for a crystal may be missing within the individual polymer layers. In addition, the structure of the individual polymer layers can also change with the thickness of the individual polymer layer.

In summary, the crystallinity of a semiconducting organic layer (also referred to as organic semiconducting layer, organic semiconducting layer, or semiconducting polymer layer) cannot be derived from the material of the layer alone. Pi-stacking can occur in both crystalline and amorphous phases of the same material.

The crystallinity of the organic, semi-leaded layer(s) is achieved in the subject-matter of the application by flash crystallization. For this purpose, an initially amorphous crystal growth layer 106 is formed, which is then converted into a crystalline crystal growth layer, for example in a thermal annealing process. The transformation or crystallization of the crystal growth layer may be carried out, for example, under an inert gas atmosphere for a predetermined time, for example, in a range from 30 s to 15 min, at a predetermined temperature, for example, in a range from 120° C to 180° C, for example, 60 s at 160° C. The crystal growth layer can then further serve as a host crystal for the epitaxial growth of further organic semiconductor layers on the crystal growth layer. Optionally, after the epitaxial growth, such as by evaporation, the further organic semiconductor layers can be converted or crystallized into a predetermined crystal structure using a thermal annealing process.

The crystal structure of the crystal growth layer can thus continue into the further organic semiconducting layers. Thus, the crystalline organic semiconducting layers can obtain their crystallinity.

Illustratively, the crystalline structure or crystallinity, for example the crystal structure or crystal system (lattice type), of the first organic semiconductor layer continues into the second organic semiconductor layer.

This enabled an organic semiconductor junction with a larger depletion region between the crystalline first and second organic semiconductor layers compared to the case where the second organic semiconductor layer is an amorphous organic layer. As a result, a controlled organic semiconductor device with improved regulation can be realized. In various embodiments, the depletion zone may be enlarged and/or adjusted by an additional (third) crystalline intrinsic organic semiconductor layer between the first and second organic semiconductor layers. In this case, the crystallinity of the first organic semiconductor layer may continue, spread, or transfer through the third organic semiconductor layer into the second organic semiconductor layer.

Further, due to the smaller parasitic capacitances, a controlled organic semiconductor device with a higher switching frequency can be enabled. From this, higher power at high frequencies, higher frequency bandwidth, higher maximum current density, and impedance matching advantages can be achieved.

In addition, compared with a controlled inorganic semiconductor device, the controlled organic semiconductor device has greater flexibility, greater transparency, low weight, low material consumption, and high adaptability, etc.

The controlled organic semiconductor device has a control terminal for controlling or regulating a current flow. The control terminal may also be referred to as a third electrode, a control electrode, a control contact, a gate electrode, or a base electrode in the context of this description and in various embodiments. The control terminal may be at least partially embedded in one of the organic semiconductor layers or surrounded by one or more organic semiconductor layers. The control terminal may be configured to provide control over the control current and to minimize parasitic leakage currents.

The terms “controlled” and “controllable” are used interchangeably in the context of this description. In particular, a “controlled device” also includes the device in the off or unpowered state (controllable device). The controlled organic semiconductor device is, for example, a transistor, for example, an organic bipolar transistor or an organic field-effect transistor; a controlled diode, for example, an organic thyristor; or a controlled diode circuit, for example, an organic triac.

The first organic semiconductor layer may be hole conductive (also referred to as p-type or p-conductive) and the second organic semiconductor layer may be electron conductive (also referred to as n-type or n-conductive). Alternatively, the first organic semiconductor layer may be electron-conductive and the second organic semiconductor layer may be hole-conductive. In a hole-conducting layer, the majority charge carriers are free-moving holes (electron vacancies) that have a higher mobility than electrons through the organic semiconductor layer. In an electron-conducting layer, the majority charge carriers are free-moving electrons that have higher mobility than holes (electron vacancies) through the organic semiconductor layer. As such, the first or second conductivity type may refer to qualitatively different conductivities in the context of this description. Alternatively or additionally, the first and second conductivity types may refer to different dopings, for example, n, p, n−, n−−, p+, p++. In the context of this description, a semiconductor layer may have a doping or dopant in a matrix or host if the semiconductor layer is not referred to as “undoped” or “intrinsic”. An undoped or intrinsic semiconductor layer may have an unintended doping.

In the context of this description, the terms “conducting” and “conductive” are used interchangeably for semiconductor layers unless the terms are explicitly used differently.

In various embodiments, the controlled organic semiconductor device may have a pin structure or a nip structure instead of a pn or np structure, i.e. an intrinsic third organic semiconductor layer between the first and second organic semiconductor layers. This allows for a thicker depletion region, for example, thus compensating for a possibly low depletion zone thickness in the organic semiconductor device or pn junction. In various embodiments, different combinations of p-conducting, n-conducting and i (intrinsic) conducting layers may be realized according to the application, for example npn, nipn, nipin, pnp, pinp, pinip or combinations thereof. The semiconductor layers or combinations may be stacked over each other and/or arranged side by side on or over the (common) substrate. For example, the die semiconductor layers or combinations may be arranged between a (common) first electrode and a (common) second electrode, such as an emitter and collector electrode or a source and drain electrode, on or over the substrate.

In various embodiments, one or more electron or hole block layer(s) (also referred to as blockade layer(s) or blocking layer(s)) to minimize parasitic currents; one or more electron or hole injection layer(s) to enhance carrier injection; and one or more electron or hole transport layer(s) to enhance carrier transport may further be provided in the layer stack of the controlled organic semiconductor device.

Using the shape or geometry of the control electrode, the type of controlled semiconductor device can be set up, for example, by adjusting from active to passive areas. In this manner, an organic bipolar transistor can be realized.

In another aspect, a method of forming a controlled organic semiconductor device is provided, the method comprising: forming a crystalline first organic semiconductor layer on or over a substrate, the first organic semiconductor layer comprising a first conductivity type; and forming a crystalline second organic semiconductor layer on or over the first organic semiconductor layer, the second organic semiconductor layer comprising a second conductivity type, the first conductivity type being different from the second conductivity type.

The first organic semiconductor layer can be formed, for example grown, on the substrate by evaporation or sublimation, and can be processed or patterned using conventional thin film technology. The length of the control electrode of the controlled organic semiconductor device can be freely set.

The first and second organic semiconductor layers are formed or based on a process such that bulk or volume doping of holes (p) and electrons (n) into a matrix material and a host material (host material), is possible.

Illustratively, the selective application of a new growth method for organic semiconductor crystals (optionally combined with chemical doping via co-evaporation) can enable organic semiconductor layers with significantly longer diffusion lengths than was previously possible in organic semiconductors.

Examples of embodiments are shown in the figures and are explained in more detail below.

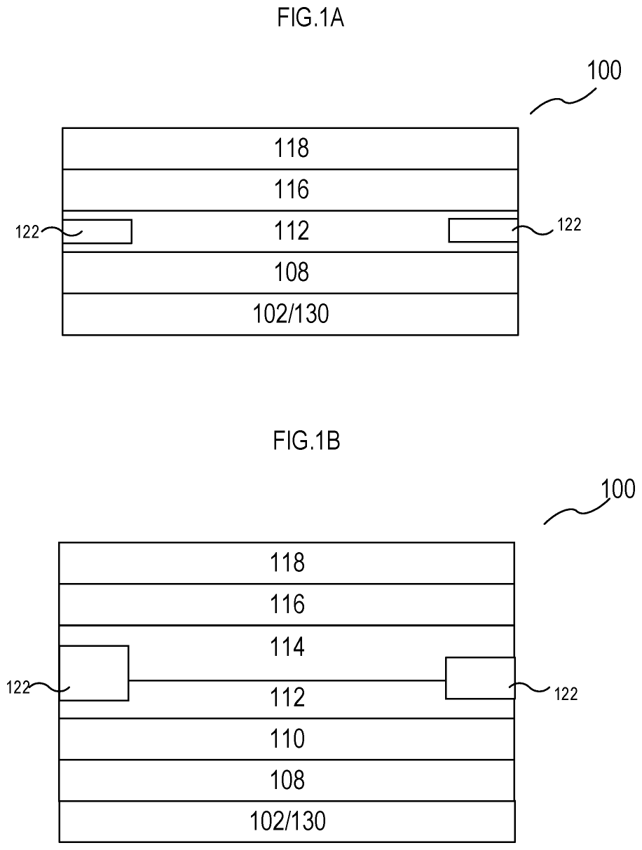

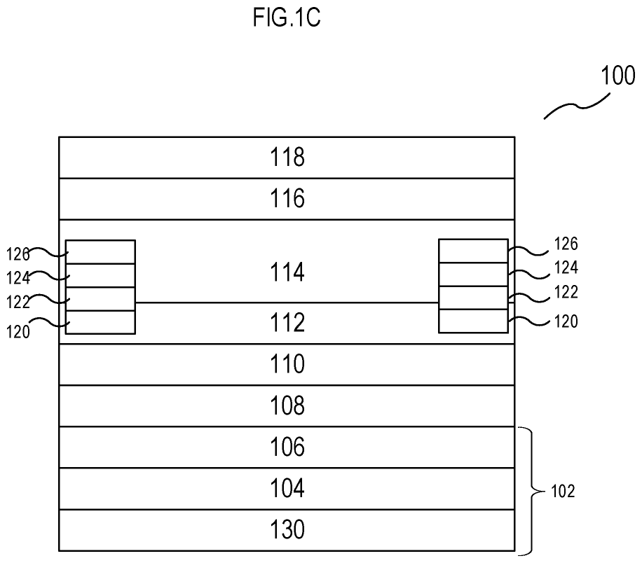

FIG. 1A depicts a schematic cross-sectional view of controlled organic semiconductor devices according to various embodiments;

FIG. 1B depicts a further schematic cross-sectional view of controlled organic semiconductor devices according to various embodiments;

FIG. 1C depicts a further schematic cross-sectional view of controlled organic semiconductor devices according to various embodiments;

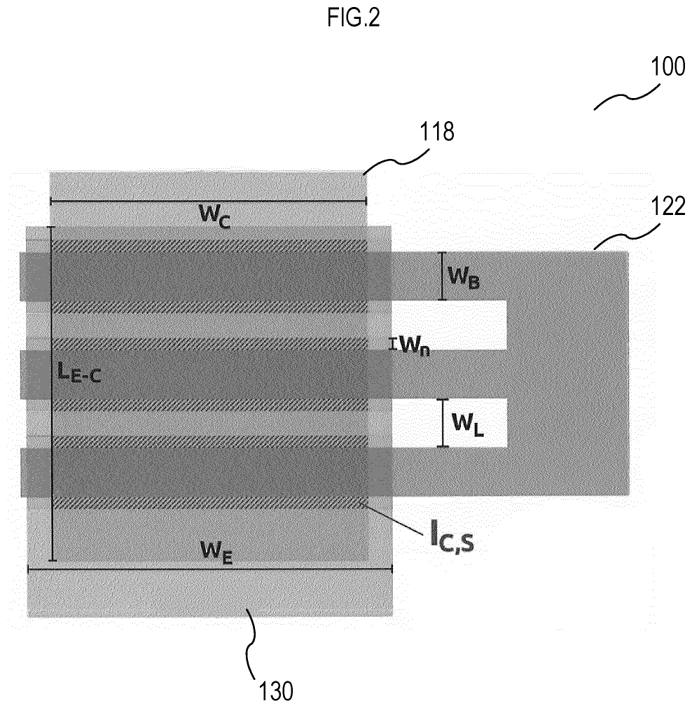

FIG. 2 depicts a schematic top view of a controlled organic semiconductor device according to various embodiments;

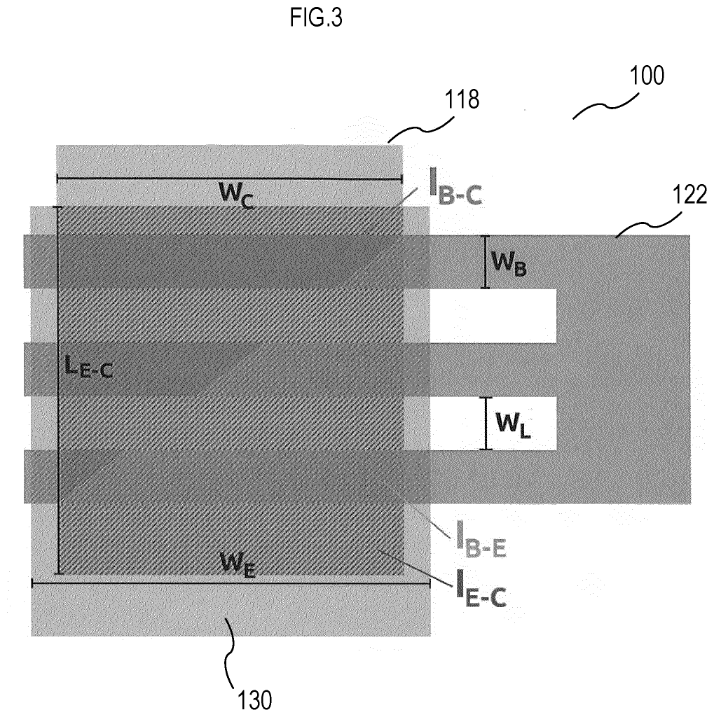

FIG. 3 depicts a schematic top view of a controlled organic semiconductor device according to various embodiments; and

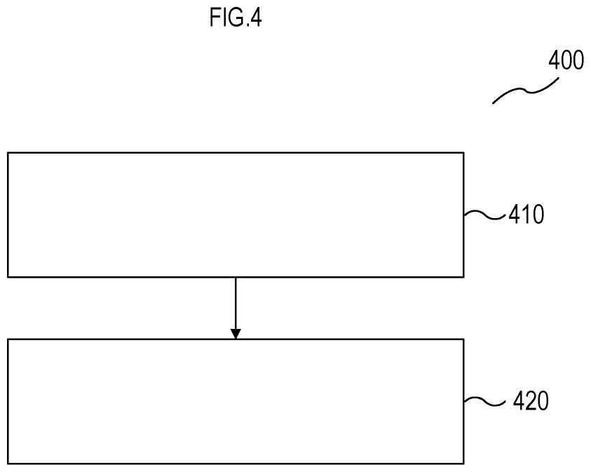

FIG. 4 depicts a flowchart of a method of fabricating a controlled organic semiconductor device according to various embodiments.

In the following detailed description, reference is made to the accompanying drawings, which form part of the description and in which specific embodiments in which the invention may be practiced are shown for illustrative purposes. It is understood that other embodiments may be used and structural or logical changes may be made without departing from the scope of protection of the present invention. It is understood that the features of the various exemplary embodiments described herein may be combined, unless specifically indicated otherwise. Therefore, the following description is not to be construed in a limiting sense, and the scope of protection of the present invention is defined by the appended claims.

FIG. 1A-C illustrate embodiments of a controlled organic semiconductor device 100 according to various embodiments.

FIG. 1A-C, illustrate embodiments of a controlled, organic semiconductor device 100 having a plurality of organic semiconductor layers 108, 110, 112, 114, 116, which may have different conduction types with respect to each other.

In various embodiments, the controlled organic semiconductor device 100 may include a first electrode 130, a second electrode 118, and a third electrode 122. The third electrode 122 is configured as a control electrode to control current flow between the first electrode 130 and the second electrode 118. The third electrode 122 may be embedded in one of the semiconductor layers 108, 110, 112, 114, 116, as illustrated in FIG. 1A. Alternatively or additionally, the third electrode 122 may be at least partially surrounded by one or more of the semiconductor layers 108, 110, 112, 114, 116, as illustrated in FIG. 1B and FIG. 1C. For example, at least a portion of the third electrode 122 is embedded in or at least partially surrounded by the second organic semiconductor layer 112, as illustrated in FIG. 1A, as illustrated in FIG. 1B and FIG. 1C. The third electrode 122 may include a patterning, wherein the patterning includes one or more finger shapes and/or a meander shape, as illustrated in FIG. 2 and FIG. 3.

The plurality of organic semiconductor layers 108, 110, 112, 114, 116 are disposed on or over a substrate 102/130. The substrate 102 may be arranged as the first electrode 130 or include the first electrode 130. For example, the substrate 102 may have additional layers in addition to the first electrode 130, such as a buffer layer 104 and/or a crystal growth layer 106, as illustrated in FIG. 1C. At least some of the organic semiconductor layers 108, 110, 112, 114, 116 are crystalline.

The crystallinity, for example the crystal structure or lattice type, or the formation of a crystal structure may extend from the first crystalline organic semiconductor layer 108 at least into the crystalline second organic semiconductor layer 112. This may allow for an increase in the size of the depletion region in the semiconductor device 100, and may result in an improvement in the control or regulation of the controlled organic semiconductor device compared to a device having an amorphous semiconductor layer. Alternatively or additionally, this may increase the switching frequency. Without crystalline organic semiconductor or with amorphous organic semiconductor, the required (long) diffusion lengths of the charge carriers at the pn junction could not be realized. Without doping, the pn junction or the energy levels may not be adjusted. Using the doped crystalline organic semiconductor layers, a controllable semiconductor device can be realized. An organic semiconductor layer with high crystallinity, for example greater than about 80% (by any measurement method), for example greater than 90%, may imply high carrier mobility. As a result, a larger edge rise can be realized at turn-on. This allows that the dead time between the switch-off timing and the switch-on timing can be reduced. As a result, an increase in switching frequency can be realized.

The second organic semiconductor layer 112 may have the same crystal structure, for example, a cubic crystal structure (bcc), as the first organic semiconductor layer 108, for example, in the case where the first and second semiconductor layers 108, 112 are formed of the same or a similar matrix material or host material.

Alternatively, with respect to material, the second organic semiconductor layer may have a crystal structure different from the crystal structure of the first organic semiconductor layer 108 that is compatible with the crystal structure of the first organic semiconductor layer 108, for example in the case where the first and second organic semiconductor layers 108, 112 are formed from the different matrix or host material. For example, the second semiconductor layer 112 may have an hcp or fcp crystal structure with a lattice constant that is the same or similar (compatible) to a lattice constant of the crystal structure (for example, bcc) of the first organic semiconductor layer 108. Thus, the first organic semiconductor layer 108 can illustratively act as a seed layer or crystal growth layer for the second organic semiconductor layer 112.

In various embodiments, the crystallinity of the first organic semiconductor layer may extend into the second organic semiconductor layer 112 through one (or more) third semiconductor layers 110 disposed between the first and second organic semiconductor layers 108, 112 (see FIG. 1B and FIG. 1C).

In various embodiments, the crystallinity of the first organic semiconductor layer may extend into one or more organic semiconductor layers on or above the second organic semiconductor layer 112, for example, into a fourth organic semiconductor layer 116 and/or into a fifth organic semiconductor layer 114.

In various embodiments, the controlled organic semiconductor device 100 is configured as an organic transistor 100, for example, as an organic bipolar transistor or an organic field effect transistor, as illustrated in FIG. 1A to FIG. 1C. The organic transistor 100 may have a pnp or an npn layer stack of organic (crystalline) semiconductor layers 108, 112, 116, as illustrated in FIG. 1A. Alternatively, the organic transistor 100 may have a pinip or nipin layer stack of organic (crystalline) semiconductor layers 108, 110, 112, 114, 116, as illustrated in FIG. 1B and FIG. 1C. Alternatively (not illustrated), the organic transistor 100 may have a different layer stack, for example, nipn, npin, npni, ipnp, pinp, pipn, pnpi, ipnp.

In various embodiments, a non-conductive layer and/or an insulating layer may further be provided in the layer stack, for example bordering the control electrode (third electrode). Thus, for example, a field effect transistor (FET) or an insulated gate bipolar transistor (IGBT) may be implemented. The insulating layer or the non-conducting layer may be an organic layer, for example a crystalline organic layer. The non-conducting organic layer may have a band gap, for example by means of no or low doping and/or corresponding crystal orientation with respect to directly adjacent semiconductor layers, leading to a non-conducting state during operation of the semiconductor device. The non-conducting layer may have a different crystal orientation, for example configured the evaporation parameters, from the directly adjacent p-, n- or i-conducting organic layer(s). An organic semiconductor layer formed on the insulating or non-conducting semiconductor layer may be crystalline, for example, single-crystalline or polycrystalline, or amorphous.

Alternatively (not illustrated), the controlled organic semiconductor device 100 may be set up as a controlled diode, for example, an organic thyristor; or a controlled diode circuit, for example, an organic triac, having a pn-, np-, nip-, or pin-layer stack of organic (crystalline) semiconductor layers 108, 110, 112, or combinations thereof, for example, ipn, inp, nipi, pini, ipni, inpi, etc.

In various embodiments, various application-specific combinations of p-type, i-type, and n-type crystalline organic semiconductor layers may be provided between the first electrode 130 and the second electrode 118 on or over the substrate 102.

In various embodiments, the combinations of semiconductor layers may be arranged side-by-side and/or stacked on or over the substrate 102. Multiple controlled organic semiconductor devices 100 may also be arranged side-by-side or stacked over each other on a common substrate 102. Multiple controlled organic semiconductor devices 100 on or over a common substrate 102 may include at least one common electrode 130, 118 in various embodiments.

As an example, the controlled organic semiconductor device 100 has a crystalline first organic semiconductor layer 108 on or over a substrate 102 and a crystalline second organic semiconductor layer 112 on or over the first organic semiconductor layer 108. The crystalline first organic semiconductor layer 108 exhibits a first conductivity type, such as p-type conductive, and the crystalline second organic semiconductor layer 112 exhibits a second conductivity type, such as n-type conductive. The first conductivity type may be different from the second conductivity type. As a result, a pn-junction with a depletion region may be formed between the first and second organic semiconductor layers 108, 112. The first organic semiconductor layer 108 may be hole conductive and/or p-doped, and the second organic semiconductor layer may be electron conductive and/or n-doped, or vice versa.

The first organic semiconductor layer 108 may have a first crystallinity, and the second organic semiconductor layer 112 may have a second crystallinity. The second crystallinity may be less than or equal to the first crystallinity. In the context of this description, the crystallinity of a layer is the relative proportion of the crystalline volume or mass of the layer to the total layer. The crystallinity can be determined using a density measurement, differential scanning calorimetry (DSC), X-ray diffraction, infrared spectroscopy, and/or nuclear magnetic resonance spectroscopy. The crystal order or crystallinity of the first organic semiconductor layer 108 extends into the second organic semiconductor layer 112 conditioned upon the manufacturing process. Therefore, the second organic semiconductor layer 112 should have the same crystallinity as the first organic semiconductor layer or have a smaller crystallinity, for example, in the case where the crystallinity is received from the first organic semiconductor layer 108 only in the vicinity of the interface with the first organic semiconductor layer 108.

The first organic semiconductor layer 108 may comprise or be formed from a first type of low molecular weight conjugated molecules.

In the context of this description, a low molecular weight conjugated molecule may be any of the following: an oligoacene, for example, anthracene, pentacene or benzenthiolate—as well as a derivative thereof; a two-dimensional fused ring system, for example, perylene, hexabenzocoronene, naphthalene, perylenetetracarboxylic dianhydride (PTCDA)—as well as a derivative thereof; a metal complex, for example, phthalocyanines (Pc), aluminum tris(8-hydroxyquinoline)—as well as a derivative thereof; a dendritic molecule, for example a starburst molecule, for example 4,4′,4″-tris(N,N-diphenyl-amino) triphenylamine (TDATA)—and a derivative thereof; or a heterocyclic oligomer, for example oligothiophenes, oligophenylenevinylenes—and a derivative thereof.

The second organic semiconductor layer 112 may comprise or be formed from a second type of low molecular weight conjugated molecules. The second type of conjugated molecules and the first type of conjugated molecules may be the same or derivatives of a same type of conjugated molecules.

For example, the first organic semiconductor layer 108 may comprise or be formed from rubrene or a derivative thereof. Alternatively or additionally, the second organic semiconductor layer 112 may comprise or be formed from rubrene or a derivative thereof.

The first organic semiconductor layer 108 may comprise a first dopant, and the second organic semiconductor layer 112 may comprise a second dopant different from the first dopant.

The second organic semiconductor layer 112 may be epitaxially formed on the first organic semiconductor layer 108, for example, using a sublimation process. Alternatively or additionally, at least the second organic semiconductor layer 112 may be free of solvents.

A crystalline third organic semiconductor layer 110 may be disposed between the first organic semiconductor layer 108 and the second organic semiconductor layer 112. The third organic semiconductor layer 110 may be undoped or substantially undoped. In other words, the third organic semiconductor layer may be an intrinsically conducting or conductive layer. The third organic semiconductor layer 110 may be directly adjacent to the first organic semiconductor layer 108 and/or the second organic semiconductor layer 112. The third organic semiconductor layer 110 may have a third crystallinity that is less than or equal to the first crystallinity of the first organic semiconductor layer 108.

A fourth organic semiconductor layer 116 may be disposed on or above the second organic semiconductor layer 112. The fourth organic semiconductor layer 116 may optionally be crystalline. The fourth organic semiconductor layer 116 may have the same or substantially the same conductivity type as the first organic semiconductor layer 108. The fourth organic semiconductor layer 116 may have a fourth crystallinity that is less than or equal to the second crystallinity of the second organic semiconductor layer 112.

A fifth organic semiconductor layer 114 may be disposed between the second organic semiconductor layer 112 and the fourth organic semiconductor layer 116. The fifth organic semiconductor layer 114 may be undoped or substantially undoped. The fifth organic semiconductor layer 114 may be directly adjacent to the second organic semiconductor layer 112 and/or the fourth organic semiconductor layer 116.

The substrate 102 may include an organic crystal growth layer 106. The first organic semiconductor layer 108 may be disposed directly on the organic crystal growth layer 106.

FIG. 1C illustrates, in a schematic cross-sectional view, an embodiment of a controlled organic semiconductor device according to various embodiments. The illustrated organic semiconductor device 100 may be a bipolar transistor and comprise thin layers of organic materials with high carrier mobility in all spatial directions.

In various embodiments, the substrate 102 comprises a layer stack. The layer stack may include the first electrode 130, the buffer layer 104, and the crystal growth layer 106. The layer stack may be formed on a carrier (not shown). For example, the carrier may comprise or be formed from a glass substrate, a plastic film, or a metallic or semiconductive material.

For example, the first electrode 130 may be or include gold. This may allow for effective hole-injection. For example, the first electrode 130 may have a thickness in a range of 10 nm to 500 nm, for example in a range of 20 nm to 50 nm, for example about 30 nm.

The buffer layer 104 may comprise or be formed from, for example, 4,4′-cyclohexylidenebis[N,N-bis(4-methylphenyl)benzenaminel] (TAPC). The buffer layer 104 may allow for improvement of the growth of the crystal growth layer 106. For example, the buffer layer 104 may have a thickness in a range of 1 nm to 20 nm, for example as in a range of 2 nm to 10 nm, for example about 5 nm.

The crystal growth layer 106 may, for example, comprise or be formed from undoped or intrinsically conductive rubrene. For example, the crystal growth layer 106 may have a thickness in a range from 5 nm to 100 nm, for example in a range from 10 nm to 50 nm, for example about 20 nm.

The crystalline first (p-type) organic semiconductor layer 108 may comprise, for example, rubrene doped with or formed from 2,3,5,6-tetrafluoro-7,7,8,8-tetracyanoquinodimethane (F6TCNNQ). For example, the first organic semiconductor layer 108 may have a thickness in a range from 50 nm to 1000 nm, such as in a range from 100 nm to 500 nm, such as about 300 nm.

The crystalline third (intrinsic) organic semiconductor layer 110 may comprise or be formed from undoped or intrinsically conductive rubrene. For example, the third organic semiconductor layer 110 may have a thickness in a range of 20 nm to 300 nm, for example in a range of 50 nm to 200 nm, for example about 100 nm.

The crystalline second (n-type) organic semiconductor layer 112 may comprise, for example, rubrene doped with tetrakis(hexahydropyrimidinopyrimidine)ditungsten(II) (W2(hpp)4) or formed therefrom. The second organic semiconductor layer 112 may have a thickness in a range from 5 nm to 100 nm, for example, in a range from 10 nm to 50 nm, for example, about 20 nm.

The (crystalline) third (intrinsic) organic semiconductor layer 114 may comprise or be formed from undoped or intrinsically conductive rubrene. The fifth organic semiconductor layer 114 may have, for example, a thickness in a range from 20 nm to 300 nm, for example in a range from 50 nm to 200 nm, for example about 100 nm.

The (crystalline) fourth (p-type) organic semiconductor layer 116 may comprise or be formed from, for example, rubrene doped with 2,3,5,6-tetrafluoro-7,7,8,8-tetracyanoquinodimethane (F6TCNNQ). For example, the fourth organic semiconductor layer 116 may have, for example, a thickness in a range of 50 nm to 1000 nm, for example in a range of 100 nm to 500 nm, for example about 300 nm.

The second electrode 118 may, for example, be or comprise gold. For example, the second electrode 118 may have a thickness in a range of 10 nm to 500 nm, in a range of 20 nm to 50 nm, or about 30 nm.

The third electrode 122 may be at least partially embedded in or surrounded by the second organic semiconductor layer 112 and/or the fifth organic semiconductor layer 114. The third electrode 122 may, for example, be or comprise aluminum. The third electrode 122 may, for example, have a thickness in a range of 10 nm to 100 nm, in a range of 25 nm to 75 nm, or about 50 nm.

One or more layers 120, 124, 128 may be provided between the third electrode 122 and the second organic semiconductor layer 112 and/or the fifth organic semiconductor layer 114 to set the field distribution in the semiconductor device 100 and/or to eliminate or reduce leakage currents. For example, an n-C60 layer 124 having a thickness in a range of 5 nm to 20 nm, for example 10 nm, may be formed vertically between the third electrode 122 and the second organic semiconductor layer 112. The charge carrier injection can be improved, for example, by using the n-C60 layer 124. An n-type conductive layer 124 analogous to the second semiconductor layer 112 may be formed vertically between the third electrode 122 and the fifth organic semiconductor layer 114 with a thickness in a range of 5 nm to 100 nm, for example 50 nm; and an intrinsically conductive layer 126 analogous to the fifth semiconductor layer 114 may be formed with a thickness in a range of 5 nm to 100 nm, for example 50 nm.

The individual layers 130, 104, 106, 108, 110, 112, 114, 116, 118, 120, 122, 124, may be epitaxially formed layer by layer, for example using a sublimation process and/or a co-evaporation process to form the doped semiconductor layers 108, 112, 116.

FIG. 2 illustrates a schematic top view of a controlled organic semiconductor device 100 according to various embodiments, which may be arranged according to a previously described embodiment.

The first electrode 130, for example as an emitter, has a width W_{E} and the second electrode 118, as a collector, has a width W_{C}. The first and second electrodes 130, 118 may each be formed (by way of example only) as rectangles. The third electrode 122, as a base, may be formed (by way of example only) with a finger structure (FIG. 2 illustrates 3 bars of width W_{B} with spacing W_{L}).

The first and second electrodes 130, 118 may overlap each other (overlap: L_{E-C}-W_{C}). The area of the third electrode 122 contributing to the controllable current is illustrated by Ic,s and is realized by the range of the field Wₙ of the third electrode 122 and the overlap (L_{E C}-W_{C}) of the first and second electrodes 130, 118.

In this respect, FIG. 2 illustrates the regions of the semiconductor device 100 that are active in operation or in which charge carriers (I_{C,S}) are transported between the first and second electrodes 130, 118.

FIG. 3 illustrates a schematic top view of a controlled organic semiconductor device according to various embodiments, which may be arranged according to a previously described embodiment.

Analogous to the designations in FIG. 2, FIG. 3 illustrates regions of the semiconductor device 100 in which leakage currents or parasitic currents may occur.

The overlap regions of first and third electrode I_{B-E}, the first and second electrode I_{E-C}, and third and second electrode IB_{B-C} are deposited. The overlap regions I_{B-E}, I_{B-C} with the third electrode contribute to the leakage current and can be reduced using blocking layers (see layers 120, 124, 126 in FIG. 1C). Alternatively, suitable masking processes can be used to reduce the width W_{B} of the finger structures and thus reduce leakage currents. The direct overlap I_{E-C} between first and second electrodes 130, 118 contributes to the leakage current, provided it is not affected by the electric field of the third electrode 122. This can be optimized by reducing the distance W_{L} of the finger structures of the third electrode.

FIG. 4 illustrates a flowchart of a method of manufacturing a controlled organic semiconductor device according to various embodiments.

The method 400 for forming a controlled organic semiconductor device 100 comprises: forming 410 a crystalline first organic semiconductor layer 108 on or over a substrate 102, wherein the first organic semiconductor layer 108 comprises a first conductivity type; and forming 420 a crystalline second organic semiconductor layer 112 on or over the first organic semiconductor layer 108, the second organic semiconductor layer 112 comprising a second conductivity type, the first conductivity type being different from the second conductivity type.

The first organic semiconductor layer 108 may be formed with a first type of low molecular weight conjugated molecules. The second organic semiconductor layer 112 may be formed with a second type of low molecular weight conjugated molecules. The second type of conjugated molecules and the first type of conjugated molecules may be the same or may be derivatives of a same type of conjugated molecules.

The first organic semiconductor layer 108 may comprise or be formed from rubrene or a derivative thereof. Alternatively or additionally, the second organic semiconductor layer 112 may comprise or be formed from rubrene or a derivative thereof.

The second organic semiconductor layer 112 may be formed on the first organic semiconductor layer 108 using an epitaxial process. Alternatively or additionally, at least the second organic semiconductor layer 112 may be formed using a solvent-free process.

At least the second organic semiconductor layer 112 may include a second dopant introduced into the second organic semiconductor layer 112 using a co-evaporation process.

The substrate 102 may include an organic crystal growth layer 106, wherein the first organic semiconductor layer 108 is formed directly on the organic crystal growth layer 106.

The method is described below using the organic semiconductor rubrene as an example.

A glass substrate may be prepared as the substrate. This process may encompass the mechanical and chemical cleaning of the surface of the glass carrier and the manipulation of the surface energy (surface tension). For example, the surface of the glass carrier may be hydrophilized, for example using a piranha solution. A gold layer 120 may be formed on the surface of the glass carrier. Depending on the desired crystal phase, the surface may further be vapor deposited with a buffer layer 104 having a specific glass transition temperature in a range of 110° C to 140° C. The buffer layer 104 can structurally decouple the following host layer or crystal growth layer 106 from the glass carrier or gold layer and can enable better crystallization. Alternatively or additionally, the material of the buffer layer 104 may be selected to enable improved injection of charge carriers.

On the buffer layer 104 or on the upper surface of the first electrode, the crystal growth layer 106 can be formed with a thickness in a range of 20 nm to 100 nm by thermal evaporation of rubrene in vacuum. The resulting layer may be substantially amorphous after evaporation.

The crystal growth layer may optionally be doped by co-evaporation with suitable chemical dopants.

The amorphous crystal growth layer 106 may be converted to a crystalline crystal growth layer 106 by a thermal annealing process. The conversion or crystallization can be carried out, for example, under an inert gas atmosphere for a predetermined time, for example, in a range from 30 s to 15 min, at a predetermined temperature, for example, in a range from 120° C to 180° C, for example, 60 s at 160° C. This may result in orthorhombic base-centered rubrene crystals.

The crystal growth layer 106 may further act as a host crystal for the epitaxial growth of the further semiconductor layers, in particular the first and second organic semiconductor layers. For example, the material (see FIG. 1C) of the optional further organic semiconductor layers 108, 110, 112, 114, 116, if any, can be formed on the crystal growth layer 105 using thermal evaporation or co-evaporation. The layer thickness of the individual layers can be selected with nanometer precision. Optionally, the optional further organic semiconductor layers 108, 110, 112, 114, 116 can be converted or crystallized into a predetermined crystal structure after evaporation using one of the thermal annealing processes.

For example, the first organic semiconductor layer 108 may be epitaxially formed with a thickness of 300 nm on the first organic semiconductor layer 108 from rubrene with 5 wt % of p-dopant F6TCNNQ using thermal co-evaporation.

The third organic semiconductor layer 110 is epitaxially formed with a thickness of 100 nm from rubrene by thermal evaporation.

The second organic semiconductor layer 112 is epitaxially formed on the third organic semiconductor layer 110 with a thickness of 10 nm to 50 nm by thermal co-evaporation of rubrene containing 1 wt % to 5 wt % W2(hpp)4.

The third electrode 122 can be patterned on top of the second semiconductor layer 110, for example, by a mask process, and optional blocking layers 120, 124, 126 can be epitaxially formed to adjust the field distribution, for example, by the mask to form the third electrode.

For example, the blocking layer can be epitaxially formed below the third electrode 122 with a thickness of 10 nm to 50 nm analogously to the second semiconductor layer using thermal co-evaporation of rubrene containing 1 wt % to 5 wt % W2(hpp)4. This can reduce the current density of the direct (and therefore parasitic) diode of the first and third electrodes. The blocking layer 120 can be epitaxially formed on top with 10 nm of C60 with 2 wt % relative to the dopant W2(hpp)4 using co-evaporation. This can improve electron injection into the third electrode. Thereupon, the third electrode 122 can be epitaxially formed of aluminum with a thickness of 40 nm by thermal evaporation.

Thereon, the blocking layer 124 can be epitaxially formed by co-evaporation of rubrene with 0.5 wt % of n-dopant W2(hpp)4 with a thickness of 50 nm. This can be a blocking layer for the parasitic diode between the second and third electrodes.

On top of this, the blocking layer 126 of rubrene (intrinsic/undoped) can be epitaxially formed with a thickness of 100 nm by thermal evaporation. This can act as a blocking layer for the parasitic diode of the second and third electrodes.

On top of or over the second organic semiconductor layer 122, the fifth organic semiconductor layer 114 can be epitaxially formed with a thickness in a range of 100 nm to 200 nm using thermal evaporation (intrinsic/undoped) of rubrene. This can act as a blocking layer for the upper part of the pinip structure.

The fourth organic semiconductor layer 116 can be epitaxially formed on the fifth organic semiconductor layer 114 with a thickness of about 300 nm, by thermal co-evaporation of rubrene doped with 5 wt % of p-dopant F6TCNNQ.

The second electrode can be epitaxially formed on the fourth organic semiconductor layer 116 with a thickness of about 30 nm by thermal evaporation of gold. This enables effective hole injection. The second electrode 118 can be formed in a patterned manner using a shadow mask.

The third electrode 122 can be formed in or with a finger or meander structure. This allows for the reduction of the direct overlap of the third electrode with the first and/or second electrode. At the same time, the edge area Wₙ (see FIG. 2) of the third electrode and the first and/or second electrode can be increased. In various embodiments, the width or breadth W_{B} of the individual fingers of the third electrode can be made as small as possible without compromising the integrity of the third electrode 122. In various embodiments, the spacing W_{L} of the individual fingers of the third electrode 122 can be made as small as possible without causing material from adjacent fingers to completely cover the area between the fingers due to shadow effects. The ideal spacing may be, for example, two times the base reach Wₙ, which may be predetermined by the lateral reach of the field of the third electrode.

The first and second electrodes may be formed in a structured manner such that there is an overlap between the first and third electrodes, between the third and second electrodes, and between the first and second electrodes. For example, the first and second electrodes may be rectangles of different sizes. In various embodiments, the direct overlap between the first and third electrodes and/or and between the second and third electrodes may be kept as small as possible. The overlap between first and second electrodes may be limited to the area that can be controlled from the third electrode. Ideally, first and second electrodes can be negative or an inverted structure (comb or finger structure) to the third electrode structure (or with a slight overlap to maintain alignment tolerances). This allows leakage currents to be minimized or reduced to a minimum. The patterning of the electrodes can be done by shadow mask evaporation or by photolithography.

The thickness of the third electrode 122 can be freely adjustable. The sequence of the individual organic semiconductor layers 108, 110, 112, 114, 116 can also be freely selected according to the application. This allows variation of the doping type and doping strength. Furthermore, the semiconductor layers 108, 110, 112, 114, 116 can be deposited in a structured manner, for example above or below the third electrode, in order to adjust the blocking or injection of charge carriers at predetermined sections locations.

The structure of the organic bipolar transistor 100 illustrated here and in FIG. 1C is based on the pinip architecture, in contrast to the pnp structure used for inorganic devices. The additional inserted intrinsic (i) organic semiconductor layers 110, 114 allow for the compensation of the weak current-blocking behavior of organic pn diodes. The design as nipin architecture (equivalent to npn) is also possible.

The following examples below are based on what is described herein and shown in the figures.

Example 1 is a controlled organic semiconductor device comprising a crystalline first organic semiconductor layer on or over a substrate, the crystalline first organic semiconductor layer comprising a first conductivity type; and a crystalline second organic semiconductor layer on or over the first organic semiconductor layer, the crystalline second organic semiconductor layer comprising a second conductivity type, the first conductivity type being different from the second conductivity type.

In Example 2, Example 1 may optionally include the first organic semiconductor layer having a first crystallinity and the second organic semiconductor layer having a second crystallinity, wherein the second crystallinity is less than or equal to the first crystallinity.

In Example 3, one of Examples 1 or 2 may optionally include the first organic semiconductor layer comprising or being formed from a first kind of low molecular weight conjugated molecules, and the second organic semiconductor layer comprising or being formed from a second kind of low molecular weight conjugated molecules, wherein the second kind of conjugated molecules and the first kind of conjugated molecules are the same or are derivatives of a same kind of conjugated molecules.

In Example 4, any one of Examples 1 to 3 may optionally include the first organic semiconductor layer comprising or being formed from rubrene or a derivative thereof; and/or optionally include the second organic semiconductor layer comprising or being formed from rubrene or a derivative thereof.

In Example 5, any one of Examples 1 to 4 may optionally include that the second organic semiconductor layer is epitaxially formed on the first organic semiconductor layer; and/or optionally include that at least the second organic semiconductor layer is free of solvent.

In Example 6, any one of Examples 1 to 5 may optionally include the first organic semiconductor layer comprising a first dopant and the second organic semiconductor layer comprising a second dopant different from the first dopant.

In Example 7, one of Examples 1 to 6 may optionally include a crystalline third organic semiconductor layer disposed between the first organic semiconductor layer and the second organic semiconductor layer, wherein the third organic semiconductor layer is undoped or substantially undoped, and wherein the third organic semiconductor layer is directly adjacent to the first organic semiconductor layer and/or the second organic semiconductor layer; and wherein the third organic semiconductor layer has a third crystallinity that is less than or equal to the first crystallinity of the first organic semiconductor layer.

In Example 8, any of Examples 1 to 7 may optionally further comprise a fourth organic semiconductor layer disposed on or over the second organic semiconductor layer, wherein the fourth organic semiconductor layer has the same or substantially the same conductivity type as the first organic semiconductor layer, and wherein the fourth organic semiconductor layer has a fourth crystallinity that is less than or equal to the second crystallinity of the second organic semiconductor layer.

In Example 9, the Example 8 may optionally further comprise a fifth organic semiconductor layer disposed between the second organic semiconductor layer and the fourth organic semiconductor layer, wherein the fifth organic semiconductor layer is undoped or substantially undoped, and wherein the fifth organic semiconductor layer is directly adjacent to the second organic semiconductor layer and/or the fourth organic semiconductor layer.

In Example 10, one of Examples 1 to 9 may optionally comprise the substrate comprising an organic crystal growth layer, wherein the first organic semiconductor layer is disposed directly on the organic crystal growth layer.

In Example 11, one of Examples 1 to 10 may optionally comprise the substrate comprising a first electrode of the controlled organic semiconductor device, and further comprising a second electrode on or above the second organic semiconductor layer.

In Example 12, one of Examples 1 to 11 may optionally further comprise a third electrode, wherein at least a portion of the third electrode is embedded in the second organic semiconductor layer.

In Example 13, example 12 may optionally comprise the third electrode having a patterning, wherein the patterning comprises one or more finger shapes and/or a meander shape.

In Example 14, one of examples 1 to 13 may optionally be configured as an organic bipolar transistor.

Example 15 is a method of forming a controlled organic semiconductor device, the method comprising: forming a crystalline first organic semiconductor layer on or over a substrate, the first organic semiconductor layer having a first conductivity type; and forming a crystalline second organic semiconductor layer on or over the first organic semiconductor layer, the second organic semiconductor layer having a second conductivity type, the first conductivity type being different from the second conductivity type.

In Example 16, Example 15 may optionally include the first organic semiconductor layer being formed with a first type of low molecular weight conjugated molecules, and the second organic semiconductor layer being formed with a second type of low molecular weight conjugated molecules, wherein the second type of conjugated molecules and the first type of conjugated molecules are the same or are derivatives of a same type of conjugated molecules.

In Example 17, one of Examples 15 or 16 may optionally include the first organic semiconductor layer comprising or being formed from rubrene or a derivative thereof; and/or optionally have the second organic semiconductor layer comprising or formed from rubrene or a derivative thereof.

In Example 18, any one of Examples 15 to 17 may optionally include the second organic semiconductor layer being formed on the first organic semiconductor layer by an epitaxial process; and/or optionally include at least the second organic semiconductor layer being formed by a solvent-free process.

In Example 19, any one of Examples 15 to 18 may optionally include at least the second organic semiconductor layer having a second dopant introduced into the second organic semiconductor layer by a co-evaporation method.

In Example 20, one of Examples 15 to 19 may optionally include that the substrate comprises an organic crystal growth layer, wherein the first organic semiconductor layer is formed directly on the organic crystal growth layer.

It is understood that functions, features, etc. described herein with respect to an apparatus may also be implemented in the same or similar manner in a method and vice versa.

1-20. (canceled)

21. A controlled organic semiconductor device comprising:
a crystalline first organic semiconductor layer on or over a substrate, the crystalline first organic semiconductor layer having a first conductivity type; and
a crystalline second organic semiconductor layer on or over the first organic semiconductor layer, the crystalline second organic semiconductor layer having a second conductivity type, the first conductivity type being different from the second conductivity type.

22. The controlled organic semiconductor device of claim 21,
wherein the first organic semiconductor layer comprises a first crystallinity, and the second organic semiconductor layer comprises a second crystallinity,
wherein the second crystallinity is less than or equal to the first crystallinity.

23. The controlled organic semiconductor device of claim 21,
wherein the first organic semiconductor layer comprises or is formed from a first type of low molecular weight conjugated molecules, and
wherein the second organic semiconductor layer comprises or is formed from a second type of low molecular weight conjugated molecules,
wherein the second kind of conjugated molecules and the first kind of conjugated molecules are the same or are derivatives of a same kind of conjugated molecules.

24. The controlled organic semiconductor device of claim 21, wherein the first organic semiconductor layer comprises or is formed from rubrene or a derivative thereof; and/or
wherein the second organic semiconductor layer comprises or is formed from rubrene or a derivative thereof.

25. The controlled organic semiconductor device of claim 21,
wherein the second organic semiconductor layer is epitaxially formed on the first organic semiconductor layer, and/or
wherein at least the second organic semiconductor layer is free of solvent.

26. The controlled organic semiconductor device of claim 21,
wherein the first organic semiconductor layer comprises a first dopant and the second organic semiconductor layer comprises a second dopant, different from the first dopant.

27. The controlled organic semiconductor device of claim 21,
further comprising a crystalline third organic semiconductor layer disposed between the first organic semiconductor layer and the second organic semiconductor layer, wherein the third organic semiconductor layer is undoped or substantially undoped, and
wherein the third organic semiconductor layer is directly adjacent to at least one of the first organic semiconductor layer and the second organic semiconductor layer; and
wherein the third organic semiconductor layer has a third crystallinity that is less than or equal to the first crystallinity of the first organic semiconductor layer.

28. The controlled organic semiconductor device of claim 21, further comprising a fourth organic semiconductor layer disposed on or above the second organic semiconductor layer, wherein the fourth organic semiconductor layer has the same or substantially the same conductivity type as the first organic semiconductor layer; and
wherein the fourth organic semiconductor layer has a fourth crystallinity that is less than or equal to the second crystallinity of the second organic semiconductor layer.

29. The controlled organic semiconductor device of claim 28, further comprising a fifth organic semiconductor layer disposed between the second organic semiconductor layer and the fourth organic semiconductor layer, wherein the fifth organic semiconductor layer is undoped or substantially undoped, and
wherein the fifth organic semiconductor layer is directly adjacent to the second organic semiconductor layer and/or the fourth organic semiconductor layer.

30. The controlled organic semiconductor device of claim 21, wherein the substrate comprises an organic crystal growth layer, wherein the first organic semiconductor layer is directly disposed on the organic crystal growth layer.

31. The controlled organic semiconductor device of claim 21, wherein the substrate comprises a first electrode of the controlled organic semiconductor device, and further comprising a second electrode on or over the second organic semiconductor layer.

32. The controlled organic semiconductor device of claim 21, further comprising a third electrode, wherein at least a portion of the third electrode is embedded in the second organic semiconductor layer.

33. The controlled organic semiconductor device of claim 32, wherein the third electrode comprises a patterning, the patterning comprising one or more finger shapes and/or a meander shape.

34. The controlled organic semiconductor device of claims 21, configured as an organic bipolar transistor.

35. A method of forming a controlled organic semiconductor device, the method comprising:
forming a crystalline first organic semiconductor layer on or over a substrate, the first organic semiconductor layer comprising a first conductivity type; and
forming a crystalline second organic semiconductor layer on or over the first organic semiconductor layer, the second organic semiconductor layer having a second conductivity type, the first conductivity type being different from the second conductivity type.

36. The method of claim 35,
wherein the first organic semiconductor layer is formed with a first type of low molecular weight conjugated molecules, and
wherein the second organic semiconductor layer is formed with a second type of low molecular weight conjugated molecules,
wherein the second kind of conjugated molecules and the first kind of conjugated molecules are the same or are derivatives of a same kind of conjugated molecules.

37. The method of claim 35,
wherein the first organic semiconductor layer comprises or is formed from rubrene or a derivative thereof; and/or
wherein the second organic semiconductor layer comprises or is formed from rubrene or a derivative thereof.

38. The method of claim 35,
wherein the second organic semiconductor layer is formed on the first organic semiconductor layer by an epitaxial process, and/or
wherein at least the second organic semiconductor layer is formed using a solvent-free process.

39. The process of claim 35,
wherein at least the second organic semiconductor layer comprises a second dopant introduced into the second organic semiconductor layer using a co-evaporation process.

40. The method of claim 35, wherein the substrate comprises an organic crystal growth layer, wherein the first organic semiconductor layer is formed directly on the organic crystal growth layer.
